(19) United States
(12) Patent Application Publication
(10) Pub. No.: US 2025/0316635 A1
(43) Pub. Date: Oct. 9, 2025

(54) SEMICONDUCTOR PACKAGE

(71) Applicant: Samsung Electronics Co., Ltd., Suwon-si (KR)

(72) Inventor: Jongyoun KIM, Suwon-si (KR)

(73) Assignee: Samsung Electronics Co., Ltd., Suwon-si (KR)

(21) Appl. No.: 18/921,253

(22) Filed: Oct. 21, 2024

(30) Foreign Application Priority Data
Apr. 9, 2024 (KR) 10-2024-0047827

(51) Int. Cl. H01L 23/00; H01L 23/13; H01L 23/29; H01L 23/31; H01L 25/065

(52) U.S. Cl. CPC H01L 24/24; H01L 23/13; H01L 23/293; H01L 23/3135; H01L 24/20; H01L 25/0657; H01L 24/19; H01L 24/32; H01L 24/33; H01L 24/73; H01L 2224/19; H01L 2224/214; H01L 2224/215; H01L 2224/24105; H01L 2224/24146; H01L 2224/244; H01L 2224/32145; H01L 2224/33181; H01L 2224/73267; H01L 2225/06562; H01L 2225/06565

(57) ABSTRACT

A semiconductor package may include a semiconductor chip stack including offset-stacked semiconductor chips, a wiring layer on the semiconductor chip stack, a vertical conductive structure connecting one of the semiconductor chips and the wiring layer, a molding layer at least partially covering the semiconductor chip stack and each side surface of the vertical conductive structure, and a passivation layer between the wiring layer and the molding layer. The wiring layer may include a pad in direct contact with the vertical conductive structure. The pad may be spaced apart from the molding layer with the passivation layer therebetween.

### CROSS-REFERENCE TO RELATED APPLICATIONS

This U.S. non-provisional patent application claims priority under 35 U.S.C. § 119 to Korean Patent Application No. 10-2024-0047827, filed on Apr. 9, 2024, in the Korean Intellectual Property Office, the entire contents of which are hereby incorporated by reference.

### BACKGROUND OF THE INVENTION

Some inventive concepts relate to a semiconductor package.

In a case where an integrated circuit chip is included in or provided in the form of a semiconductor package, it may be used as a portion of an electronic product. In general, a semiconductor package include a printed circuit board (PCB) and a semiconductor chip which is mounted on the PCB and is electrically connected to the PCB by bonding wires and/or bumps. With development of the semiconductor industry, studies are being conducted to improve reliability and/or durability of such semiconductor packages.

### SUMMARY

Inventive concepts relate to a structure of a semiconductor package with increased reliability and to methods of manufacturing the same.

A semiconductor package according to some example embodiments of inventive concepts may include a semiconductor chip stack including offset-stacked semiconductor chips, a wiring layer on the semiconductor chip stack, a vertical conductive structures connect one of the semiconductor chips to the wiring layer, a molding layer at least partially covering the semiconductor chip stack and each side surface of the vertical conductive structures and a passivation layer between the wiring layer and the molding layer, wherein the wiring layer includes a pad in direct contact with the vertical conductive structure, and the pad is spaced apart from the molding layer with the passivation layer therebetween.

A semiconductor package according to some example embodiments of inventive concepts may include a semiconductor chip stack including offset-stacked semiconductor chips, a wiring layer spaced apart from the semiconductor chip stack, a vertical conductive structure connecting one of the semiconductor chips to the wiring layer, and a molding layer at least partially covering the semiconductor chip stack and each side surface of the vertical conductive structure, wherein the vertical conductive structure includes a protruding portion that extends from the molding layer toward the wiring layer.

A semiconductor package according to some example embodiments of inventive concepts may include a support substrate, a semiconductor chip stack including offset-stacked semiconductor chips on the support substrate, a wiring layer on the semiconductor chip stack, vertical conductive structures connecting each of the semiconductor chips and the wiring layer, a first molding layer at least partially covering the semiconductor chip stack and each side surface of the vertical conductive structures, a passivation layer between the wiring layer and the first molding layer, a dummy structure on the support substrate, and a second molding layer at least partially covering a side surface of the first molding layer and interposed between the dummy structure and the passivation layer, wherein the wiring layer includes a pad in contact with the vertical conductive structures and with the passivation layer, and includes an insulating material different from a material of the passivation layer, or the passivation layer includes an insulating material that different from a material in the first molding layer.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 illustrates a semiconductor package according to some example embodiments of inventive concepts.

FIG. 2 is an enlarged view of AA′ in FIG. 1.

FIG. 3 is an enlarged view corresponding to AA′ in FIG. 1.

FIG. 4 is an enlarged view corresponding to AA′ in FIG. 1.

FIG. 5 is an enlarged view of BB′ in FIG. 1.

FIG. 6 is an enlarged view corresponding to BB′ in FIG. 1.

FIG. 7 is an enlarged view of CC′ of FIG. 1.

FIGS. 8, 9, 10, 11, 12, 13, 15, 18, and 20 illustrate a manufacturing process of a semiconductor package according to some example embodiments of inventive concepts.

FIG. 14 is an enlarged view of CC′ of FIG. 13 and illustrates the manufacturing process of a semiconductor package.

FIGS. 16A, 16B, 16C, and 16D are enlarged views of DD′ in FIG. 15 and illustrate the manufacturing process of a semiconductor package.

FIGS. 17A, 17B, and 17C are enlarged views of EE′ of FIG. 15 and illustrate the manufacturing process of a semiconductor package.

FIGS. 19A, 19B, 19C, 19D, and 19E are enlarged views of FF′ of FIG. 18 and illustrate the manufacturing process of a semiconductor package.

FIG. 21 is a cross-sectional view of a semiconductor package according to some example embodiments of inventive concepts.

FIG. 22 is a cross-sectional view of a semiconductor package according to some example embodiments of inventive concepts.

FIG. 23A is a cross-sectional view of a semiconductor package according to some example embodiments of inventive concepts.

FIG. 23B is an enlarged view of GG′ in FIG. 23A.

FIG. 23C is an enlarged view corresponding to GG′ in FIG. 23A.

FIG. 23D is an enlarged view of HH′ in FIG. 23A.

FIG. 24A is a cross-sectional view of a semiconductor package according to some example embodiments of inventive concepts.

FIG. 24B is an enlarged view of II″ of FIG. 24A.

### DETAILED DESCRIPTION

Hereinafter, a semiconductor package according to the inventive concept will be described with reference to the drawings.

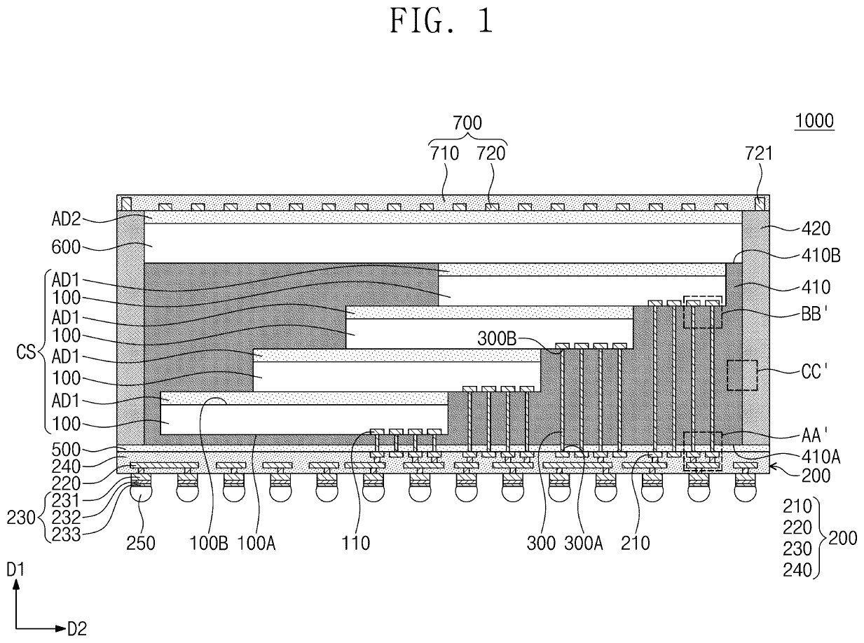

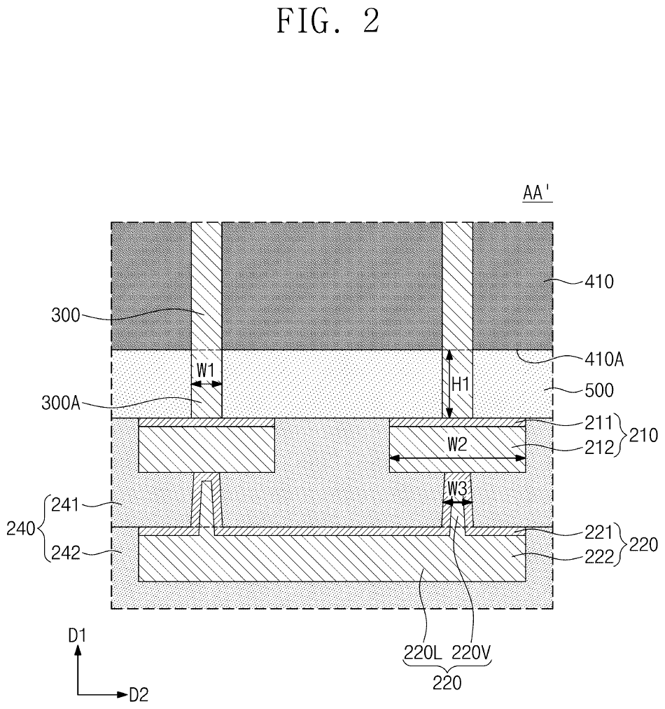

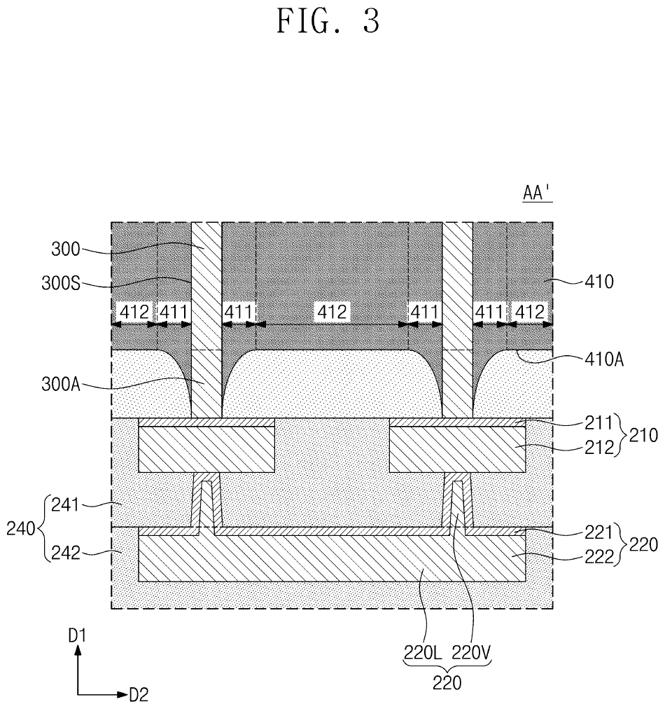

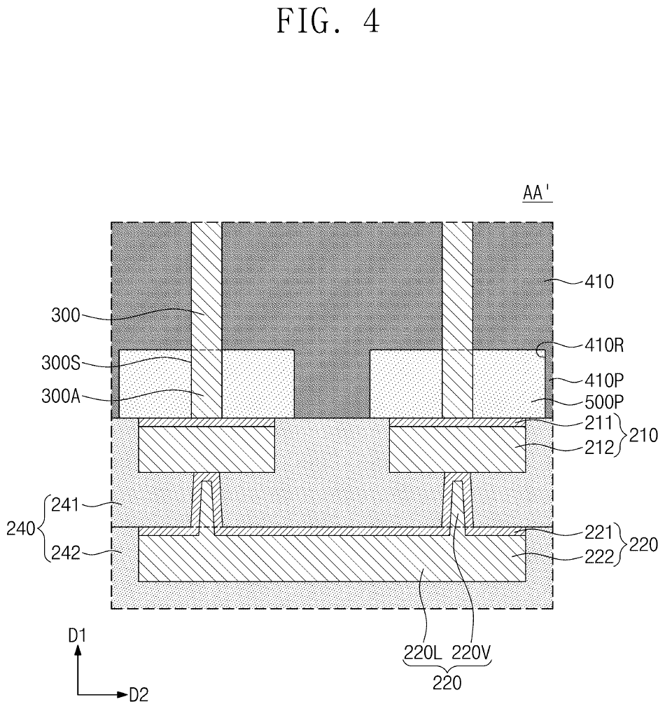

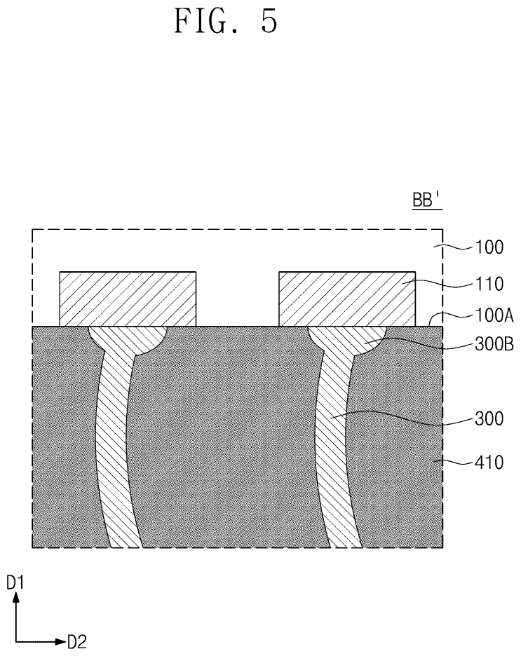

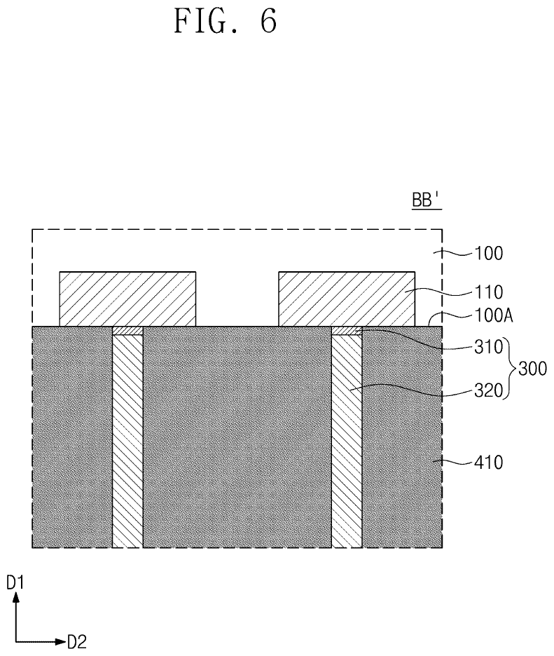

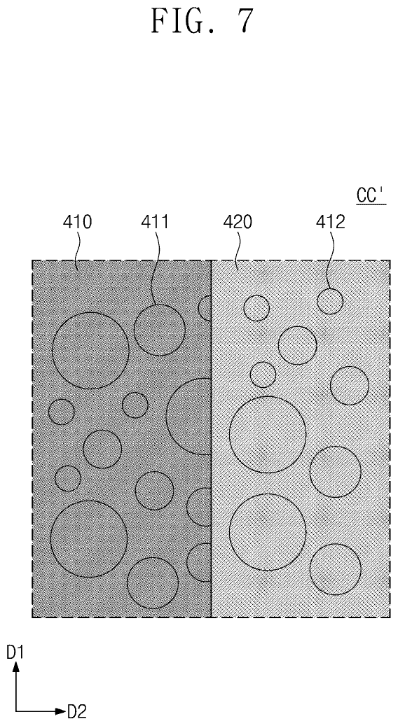

FIG. 1 illustrates a semiconductor package according to some example embodiments of inventive concepts. FIG. 2 is an enlarged view of AA′ in FIG. 1. FIG. 3 is an enlarged view corresponding to AA′ in FIG. 1. FIG. 4 is an enlarged view corresponding to AA′ in FIG. 1. FIG. 5 is an enlarged view of BB′ in FIG. 1. FIG. 6 is an enlarged view corresponding to BB′ in FIG. 1. FIG. 7 is an enlarged view of CC′ of FIG. 1.

Referring to FIG. 1, a semiconductor package 1000 according to an embodiment of the inventive concept may include a semiconductor chip stack CS, a wiring layer 200, a vertical conductive structure 300, a first molding layer 410, and a passivation layer 500.

The semiconductor chip stack CS may include offset-stacked semiconductor chips 100 and first adhesive layers AD1 interposed therebetween.

Any of each semiconductor chips 100 may be or include either a logic chip or a memory chip. Any or each of the semiconductor chips 100 may include an application specific integrated circuit (ASIC), a central processing unit (CPU), a graphics processing unit (GPU), an application processor (AP), a dynamic random access memory (DRAM), a static random access memory (SRAM), and NAND-FLASH. For example, each of the semiconductor chips 100 may be a DRAM having a same integrated circuit, but example embodiments are not limited thereto.

Each of the semiconductor chips 100 may include a first surface 100A and a second surface 100B opposing first surface 100A. The first surface 100A of the semiconductor chip 100 may be, for example, an active surface on which an integrated circuit is placed. Chip pads 110 may be disposed on the first surface 100A of the semiconductor chip 100. The chip pads 110 may be disposed adjacent to one edge of the first surface 100A of the semiconductor chip 100. The chip pads 110 may be disposed close to one of the two opposing sides of the semiconductor chip 100 and far from the other side thereof. However, example embodiments are not limited thereto, and arrangement of the chip pads 110 may be variously changed depending on design.

A first adhesive layer AD1 may be disposed on the second surface 100B of the semiconductor chip 100. In this specification, a first direction D1 refers to a direction perpendicular to the second surface 100B of the semiconductor chip 100. In this specification, a second direction D2 refers to a direction parallel to the second surface 100B of the semiconductor chip 100. In this specification, the offset stacking of the semiconductor chips 100 may mean that adjacent semiconductor chips 100 are diagonally stacked with each other in the first direction D1, the semiconductor chips 100 are arranged adjacent to each other in the first direction D1 and the second direction D2, or side surfaces of the semiconductor chips 100 adjacent to each other in the first direction D1 do not overlap each other in the first direction D1.

The first adhesive layer AD1 may be interposed between the second surface 100B of a semiconductor chip 100 disposed therebelow and the first surface 100A of a semiconductor chip 100 disposed adjacent to an upper portion to be bonded therebetween. The chip pad 110 of the semiconductor chip 100 disposed on an upper portion may be exposed from (for example, uncovered or at least partially uncovered by) the first adhesive layer AD1. The first adhesive layer AD1 may be, for example, a die attach film (DAF). The first adhesive layer AD1 may include, for example, one or more polymers material such as, for example, epoxy resin, polyimide, and acrylate, but example embodiments are not limited thereto.

The wiring layer 200 may be spaced apart from the semiconductor chip stack CS in the first direction D1. The wiring layer 200 may be, for example, a redistribution layer. The wiring layer 200 may include a first pad 210, a redistribution pattern 220, a second pad 230, and a first insulating layer 240. The first pad 210 may be referred to as a landing pad in this specification. One surface of the first pad 210 and one surface of the second pad 230 may be exposed from (for example, uncovered or at least partially uncovered by) (for example, uncovered or at least partially uncovered by) the first insulating layer 240. The redistribution pattern 220 may be interposed in the first insulating layer 240. The redistribution pattern 220 may connect (for example, electrically connect) the first pad 210 and the second pad 230 to each other. The first pad 210 may be in contact (for example, direct contact) with a vertical conductive structure 300, which will be described later. Connection terminals 250 may be disposed on the second pad 230. The connection terminals 250 may be, for example, bumps or solder balls. At least some of the connection terminals 250 may be arranged diagonally from the chip stack CS. That is, the semiconductor package 1000 may be, for example, a fan-out package. The first pad 210, the redistribution pattern 220, and the second pad 230 may each include a metal material. The second pad 230 may include a first metal layer 231, a second metal layer 232, and a third metal layer 233. The second metal layer 232 may include at least one a metal material different from (for example, not included in) the first metal layer 231 and the third metal layer 233. The first metal layer 231 and the third metal layer 233 may include the same metal material(s) or different metal materials. For example, the first metal layer 231 may contain copper, the second metal layer 232 may contain nickel, and the third metal layer 233 may contain gold, but example embodiments are not limited thereto. The first insulating layer 240 may include a photo-imageable dielectric (PID). The photo-imageable dielectric may include, for example, a polymer material such as polyimide, benzocyclobutene (BCB), etc., but example embodiments are not limited thereto.

The vertical conductive structures 300 may be interposed between each of the semiconductor chips 100 and the wiring layer 200. Each of the vertical conductive structures 300 may be, for example, a metal wire. The metal wire may include at least one of gold, copper, and palladium. A first end portion 300A of the vertical conductive structure 300 may be in contact (for example, direct contact) with the first pad 210 of the wiring layer 200, and a second end portion 300B may be in contact (for example, direct contact) with the chip pad 110. Any or each of the vertical conductive structures 300 may extend in the first direction D1.

The first molding layer 410 may cover the first surface 100A and side surfaces of the semiconductor chip 100, an upper surface and side surfaces of the first adhesive layer AD1, an upper surface of the passivation layer 500, and a side surface of the vertical conductive structures 300. For example, the first molding layer 410 may include an insulating resin such as, for example, epoxy molding compound (EMC), but example embodiments are not limited thereto. The first molding layer 410 may have an opposing first surface 410A and a second surface 410B, the first surface 410A may be in contact (for example, direct contact) with the passivation layer 500, and the second surface 410B may be in contact (for example, direct contact) with a support substrate 600 to be described later.

The passivation layer 500 may be interposed between the first molding layer 410 and the wiring layer 200. The passivation layer 500 may include, for example, one or more insulating materials. The passivation layer 500 may include a material different from that of (for example, not included in) the first molding layer 410. For example, the passivation layer 500 may include the same or similar photo-imageable dielectric as the first insulating layer 240, but example embodiments are not limited thereto.

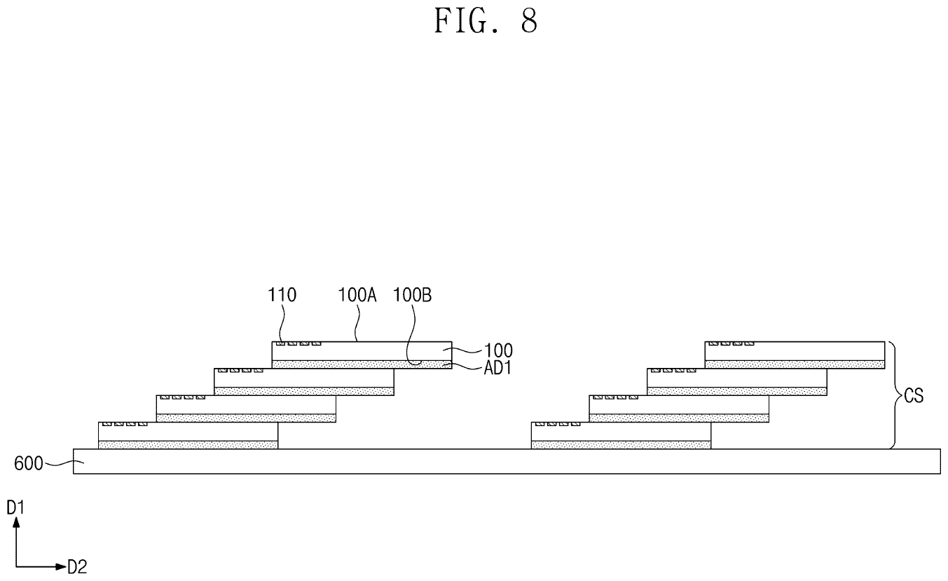

The semiconductor package 1000 may further include a support substrate 600. The support substrate 600 may be disposed on the uppermost semiconductor chip 100 of the semiconductor chip stack CS. The uppermost semiconductor chip 100 may be coupled to the support substrate 600 through the first adhesive layer AD1 disposed on the second surface 100B of the uppermost semiconductor chip 100. The support substrate 600 may be or include one of, for example, a semiconductor substrate (e.g., silicon substrate), a metal substrate, and/or a polymer substrate, but example embodiments are not limited thereto. The support substrate 600 may be a substrate on which the semiconductor chip stack CS is disposed, as will be described later with reference to FIG. 8. Additionally, for example, the support substrate 600 may function as a heat dissipation substrate that dissipates heat emitted from the semiconductor chip stack CS.

The semiconductor package 1000 may further include a dummy structure 700 and a second adhesive layer AD2. The dummy structure 700 may be disposed on the support substrate 600. The second adhesive layer AD2 may be interposed between the dummy structure 700 and the support substrate 600. For example, the second adhesive layer AD2 may include the same or similar material as the first adhesive layer AD1, but example embodiments are not limited thereto. The dummy structure 700 may include a second insulating layer 710 and a metal pattern 720 disposed in the second insulating layer 710. The second insulating layer 710 may include the same or similar material as the first insulating layer 240, but example embodiments are not limited thereto. The metal pattern 720 may include the same or similar material as the redistribution pattern 220. The dummy structure 700 may, for example, further include an align key 721 and a marking pattern, but example embodiments are not limited thereto.

The semiconductor package 1000 may further include a second molding layer 420. The second molding layer 420 may be disposed between the passivation layer 500 and the dummy structure 700. The second molding layer 420 may cover a side surface of the first molding layer 410, a side surface of the support substrate 600, and a side surface of the first molding layer 410. The second molding layer 420 may, for example, include the same or similar material (e.g., EMC) as the first molding layer 410, but example embodiments are not limited thereto.

Referring to FIGS. 1 and 2, the first molding layer 410 and the first pad 210 may be spaced apart in the first direction D1 with the passivation layer 500 therebetween. The first pad 210 may include a first seed pattern 211 and a first conductive pattern 212. The first seed pattern 211 may include, for example, titanium, copper, and/or alloy an thereof, but example embodiments are not limited thereto. The first conductive pattern 212 may include, for example, copper, but example embodiments are not limited thereto. That is, the first seed pattern 211 may be spaced apart from the first molding layer 410 in the first direction D1 with the passivation layer 500 interposed therebetween. The passivation layer 500 may be in contact (for example, direct contact) with the first molding layer 410 and the first seed pattern 211. The vertical conductive structure 300 may extend in the first direction D1 across (for example, through) the first molding layer 410 and the passivation layer 500. A first end portion 300A of the vertical conductive structure 300 may be in contact (for example, direct contact) with the first seed pattern 211. The vertical conductive structure 300 may protrude from the first molding layer 410 toward the wiring layer 200. For example, the vertical conductive structure 300 may include a portion that protrudes (for example, extends) from the first molding layer 410 by a first length H1. The first length H1 may be, for example, about 0.1 μm to 2 μm, but example embodiments are not limited thereto. The first length H1 may be equal or substantially equal to a thickness of the passivation layer 500. A side surface of the protruding portion of the vertical conductive structure 300 may be exposed from (for example, uncovered or at least partially uncovered by) the first molding layer 410. The passivation layer 500 may cover or at least partially cover the side surface of the protruding portion of the vertical conductive structure 300 that is exposed from (for example, uncovered or at least partially uncovered by) the first molding layer 410.

The vertical conductive structure 300 may have a first width W1 or a first diameter W1 in the second direction D2. The first width W1 may be, for example, about 30 μm or less, but example embodiments are not limited thereto. The first pad 210 may not include a via portion in contact (for example, direct contact) with the vertical conductive structure 300. The first pad 210 may have a shape of a cylinder or a square column whose diameter is larger than a height thereof, or substantially so. The first pad 210 may have a second width W2 or a second diameter W2 in the second direction D2. The second width W2 of the first pad 210 may be three or more times larger than the first width W1 of the vertical conductive structure 300. A contact region between the vertical conductive structure 300 and the first pad 210 may be equal substantially equal to a cross-sectional area of the vertical conductive structure 300.

Some of the redistribution patterns 220 may be in contact (for example, direct contact) with the first pad 210. The redistribution pattern 220 may include a via portion 220V and a line portion 220L. For example, the via portion 220V of the redistribution pattern 220 may be in contact (for example, direct contact) with the first pad 210. The via portion 220V may connect the first pad 210 and the line portion 220L at a different level in the first direction D1. Alternatively, the via portion 220V may connect the line portion 220L of different redistribution pattern 220 at a different level in the first direction. The via portion 220V may transmit electrical signals in the first direction D1. The line portion 220L may have a shape that extends in the second direction D2. The line portion 220L may transmit an electrical signal in the second direction D2. The via portion 220V may have a third width W3 or a third diameter W3 in the second direction D2, and the third width W3 may be smaller than the first width W1 of the vertical conductive structure 300. The third width W3 of the via portion 220V of the redistribution pattern 220 may decrease in the first direction D1. The second width W2 of the via portion 220V may be, for example, about 8 μm to 10 μm, but example embodiments are not limited thereto. The redistribution pattern 220 may include a second seed pattern 221 and a second conductive pattern 222. The second seed pattern 221 and the second conductive pattern 222 may include a same or similar metal material as the first seed pattern 211 and the first conductive pattern 212, respectively.

The first insulating layer 240 may include a plurality of insulating layers. For example, the first insulating layer 240 may include a first sub-insulating layer 241 and a second sub-insulating layer 242 on the first sub-insulating layer 241. The first sub-insulating layer 241 may cover a side surface and a lower surface of the first pad 210. The via portion 220V of the redistribution pattern 220 may cross (for example, extend through) the first sub-insulating layer 241 and may be in contact (for example, direct contact) with the first conductive pattern 212 of the first pad 210. The second sub-insulating layer 242 may cover (for example, at least partially cover) a side surface and a lower surface of the first sub-insulating layer 241 and/or the redistribution pattern 220.

According to inventive concepts, the semiconductor package 1000 may be directly connected to the first pad 210 whose diameter is, for example, more than three times larger than that of the vertical conductive structure 300, accordingly preventing or reducing misalignment. When the first pad 210 is omitted and the vertical conductive structure 300 has a first diameter W1 of 30 μm or less, the redistribution pattern may have a third diameter W3 of 8 μm to 10 μm. When directly connected to the via portion 220V of 220, both the first diameter W1 and the second diameter W2 may be small, thereby generating misalignment or substantial misalignment.

According to some example embodiments of inventive concepts, the first end portion 300A of the vertical conductive structure 300 may be connected to the first pad 210 across (for example, through) the first molding layer 410 and the passivation layer 500. The first seed pattern 211 of the first pad 210 may be spaced apart from the first molding layer 410 and may be in contact (for example, direct contact) with the passivation layer 500. A bonding force between the first seed pattern 211 (e.g., Ti) and the passivation layer 500 (e.g., polyimide) may be greater or substantially greater than a bonding force between the seed pattern 211 and the first molding layer 410 (e.g., epoxy molding compound), accordingly reducing delamination. In addition, forming the first seed pattern 211 on the passivation layer 500 may prevent or reduce the occurrence of foreign particles from being formed and redeposited, compared to forming the first seed pattern 211 on the first molding layer 410.

For the above reasons, reliability of the semiconductor package may eventually increase.

Referring to FIGS. 1 and 3, according to some example embodiments, the first molding layer 410 may include a first portion 411 and a second portion 412 disposed between adjacent vertical conductive structures 300 in the second direction D2. The first portion 411 may be disposed closer to the vertical conductive structure 300 than is the second portion 412. The first portion 411 may be in contact (for example, direct contact) with a side surface of the vertical conductive structure 300. The first portion 411 of the first molding layer 410 may protrude (for example, extend) from a first surface 410A of the first molding layer 410. A level of a lower surface of the first portion 411 may increase as a distance increases from a side surface 300S of the vertical conductive structure 300. The first portion 411 may be spaced apart from the first seed pattern 211 in the first direction D1. A change in level of the lower surface of the second portion 412 of the first molding layer 410 may be constant in the second direction D2, compared to a change in level of the lower surface of the first portion 411. The level of the lower surface of the first portion 411 of the first molding layer 410 may be lower than the level of the lower surface of the second portion 412 of the first molding layer 410. The side surface 300S of the first end portion 300A of the vertical conductive structure 300 may be in contact (for example, direct contact) with the first portion 411 of the first molding layer 410.

Referring to FIGS. 1 and 4, according to some example embodiments, the first molding layer 410 may include (for example, define or at least partially defined) a plurality of recesses 410R that respectively expose the vertical conductive structures 300. The first molding layer 410 may include a protrusion 410P interposed between the recesses 410R. The protrusion 410P of the first molding layer 410 may be in contact (for example, direct contact) with the first sub-insulating layer 241 of the wiring layer 200. Instead of the passivation layer 500, a protective pattern 500P, for example may be provided in the recess 410R. The protective pattern 500P may include the same material as the passivation layer 500. A plurality of protective patterns 500P may be provided and may be in the recesses 410R, respectively. The protective pattern 500P may cover or at least partially cover the side surface of the vertical conductive structure 300 exposed to the recess 410R. The protective pattern 500P may be in contact (for example, direct contact) with the first molding layer 410 and the first seed pattern 211.

Referring to FIGS. 1 and 5, when the vertical conductive structure 300 is a metal wire, at least a portion of the vertical conductive structure 300 may have a curved or substantially curved shape. Additionally, or alternatively, the second end portion 300B of the vertical conductive structure 300, where the metal wire is bonded to the chip pad 110, may have a shape of a ball, but example embodiments are not limited thereto.

Referring to FIGS. 1 and 6, according to some example embodiments, the vertical conductive structure 300 may include a metal pillar 320 instead of a metal wire. The vertical conductive structure 300 may further include a third seed pattern 310 between the chip pad 110 and the metal pillar 320. The third seed pattern 310 may include the same or similar metal material as the first seed pattern 211. As an example, the metal pillar 320 may be a copper pillar, but example embodiments are not limited thereto. The metal pillar 320 may have a line shape in the first direction D1.

Referring to FIGS. 1 and 7, an interface may be distinguished or defined between the first molding layer 410 and the second molding layer 420. As an example, the first molding layer 410 and the second molding layer 420 may include, for example, spherical fillers 411 and 412, respectively. The filler 411 having a cut shape of the first molding layer 410 may be disposed on the interface between the first molding layer 410 and the second molding layer 420. The fillers 411 and 412 may include insulating materials such, for example, as silica and/or alumina, but example embodiments are not limited thereto.

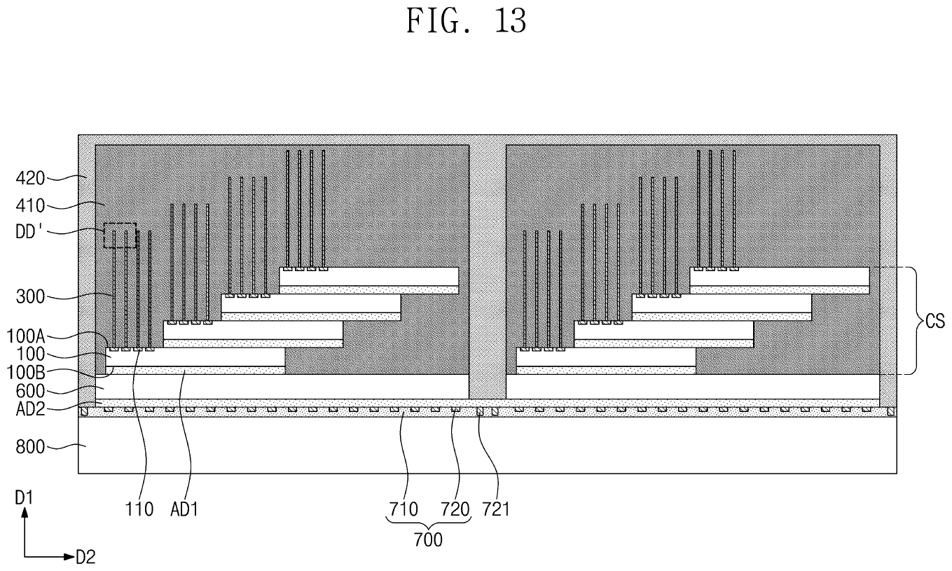

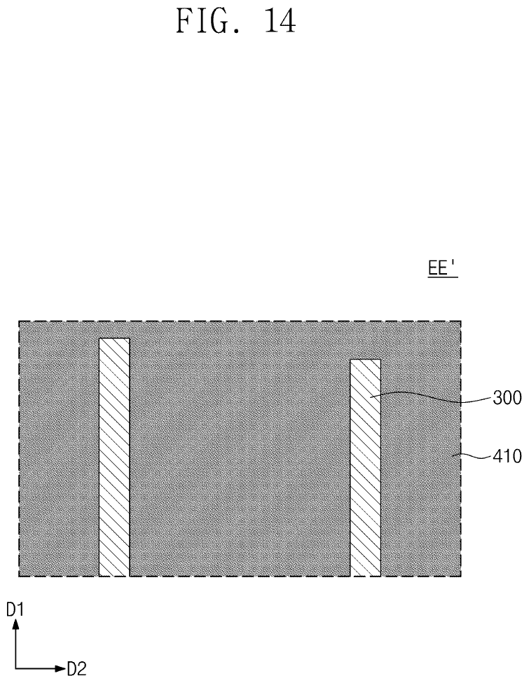

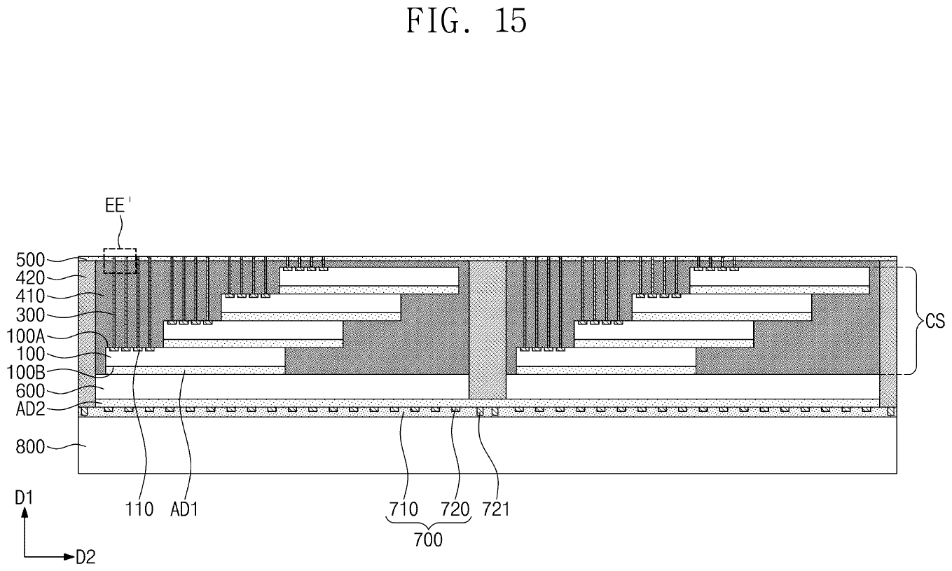

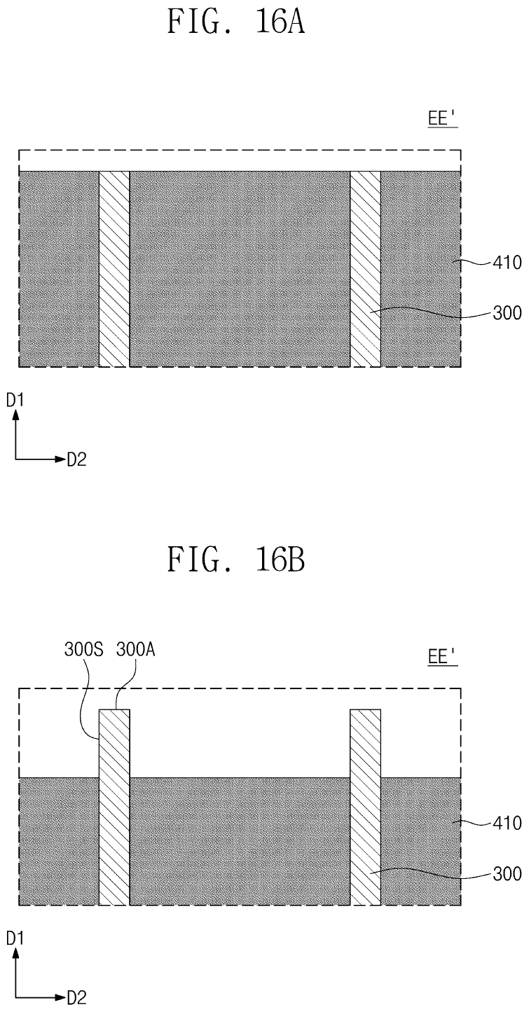

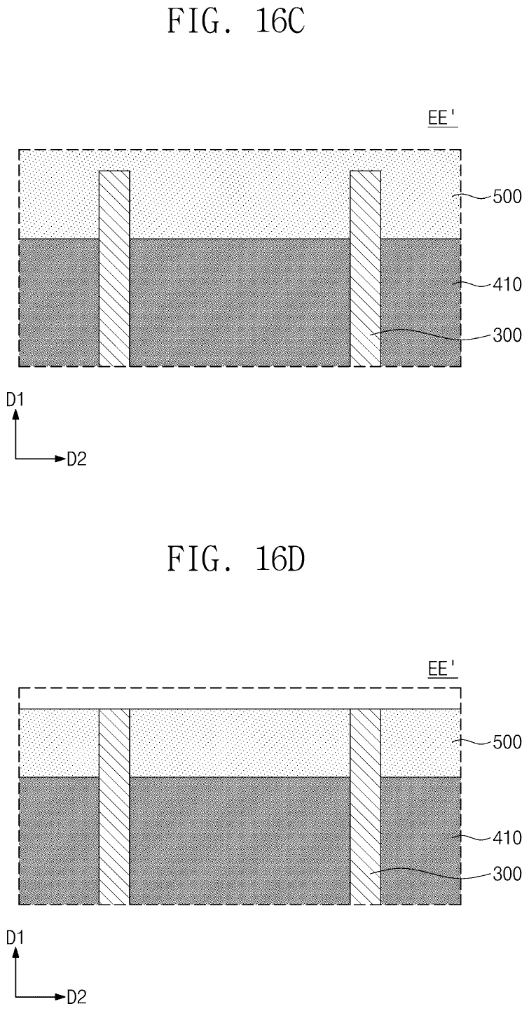

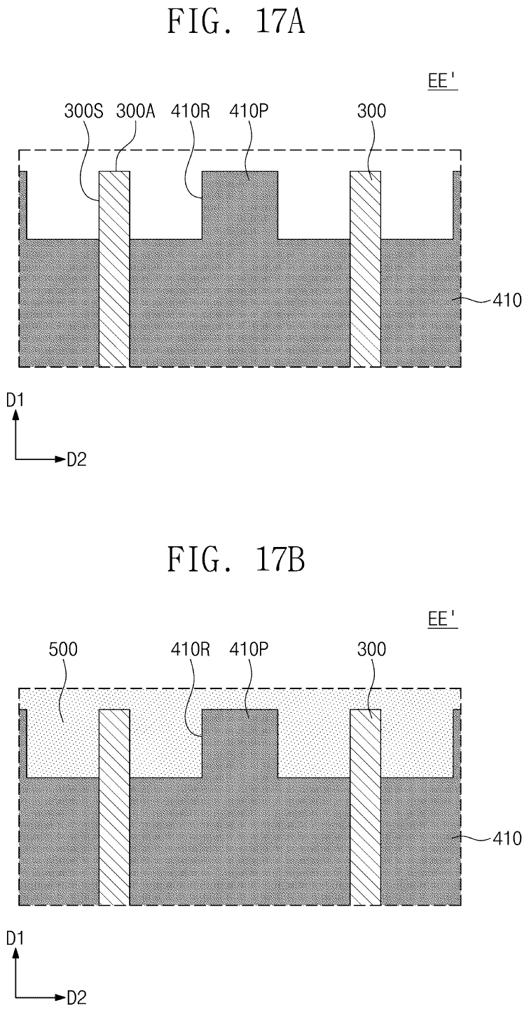

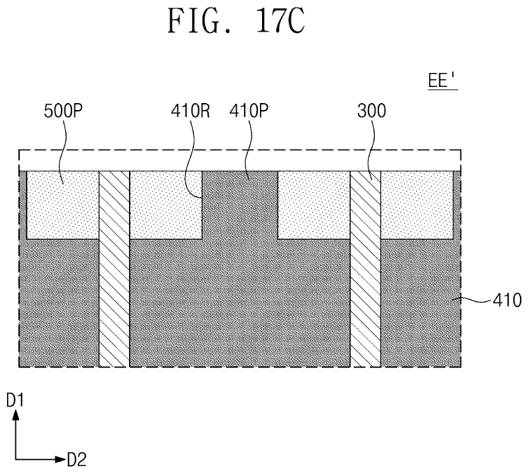

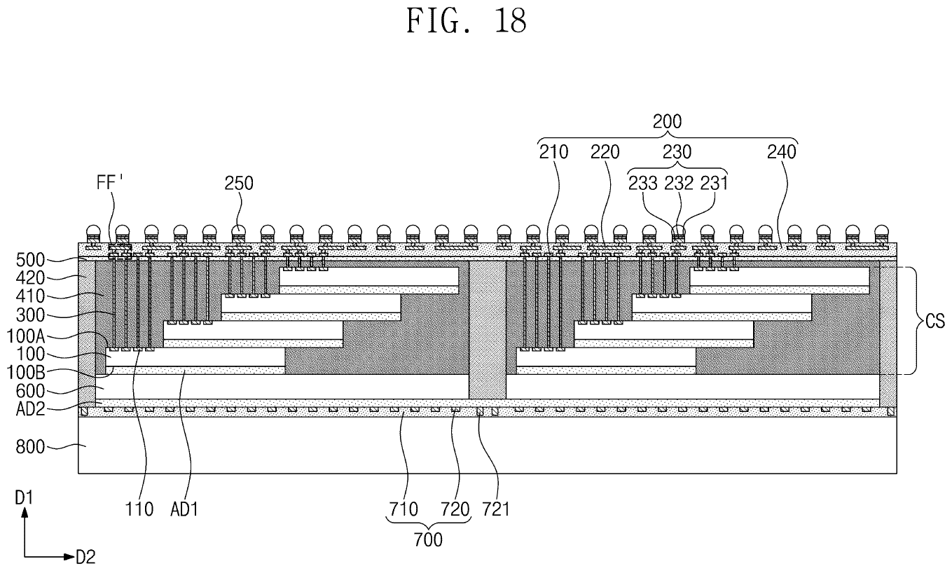

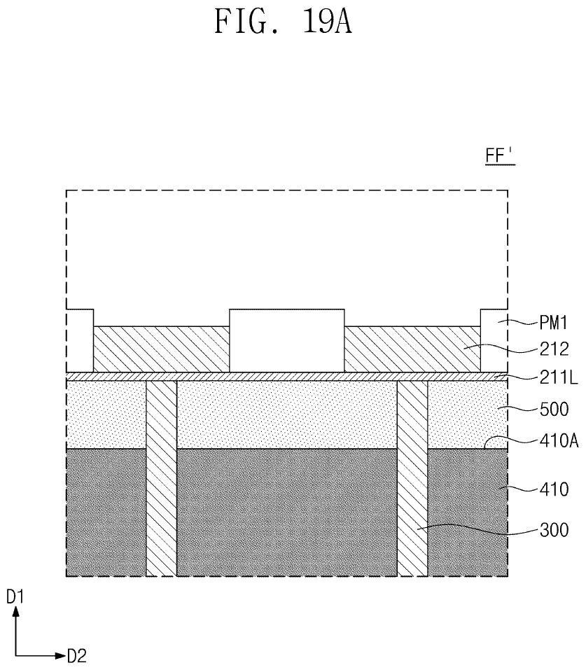

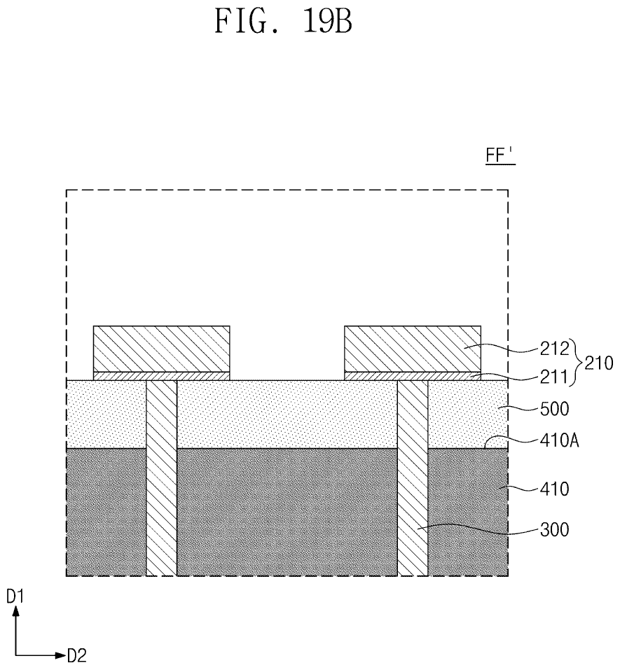

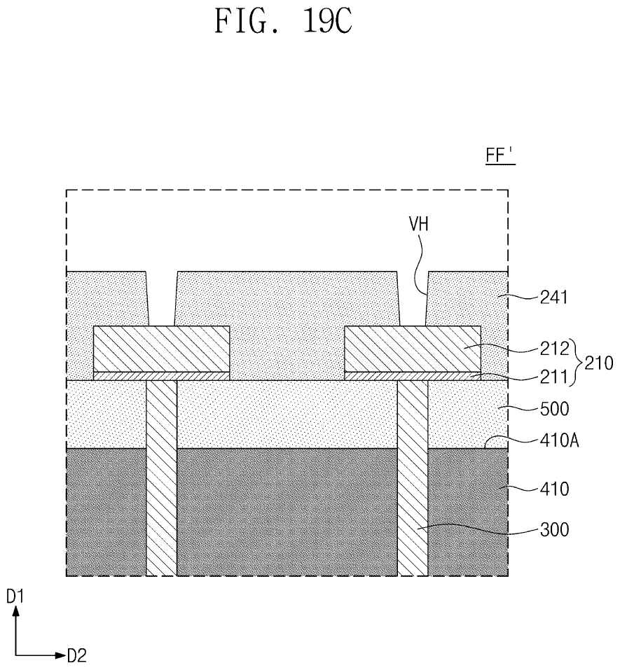

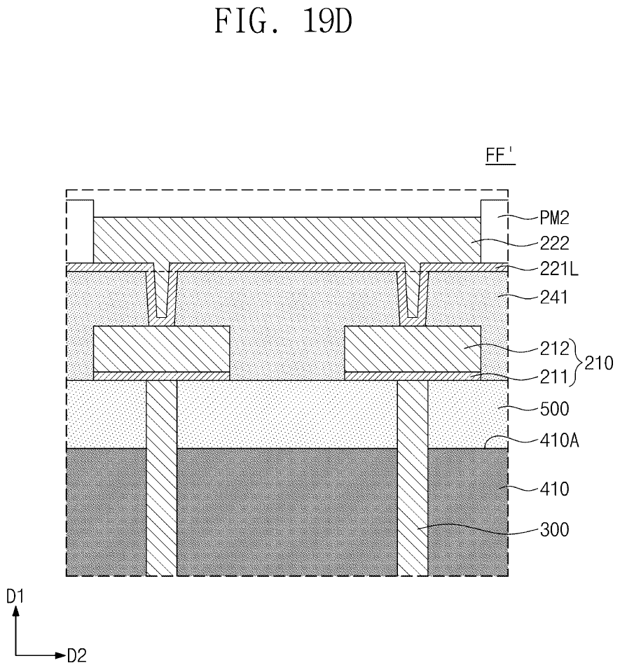

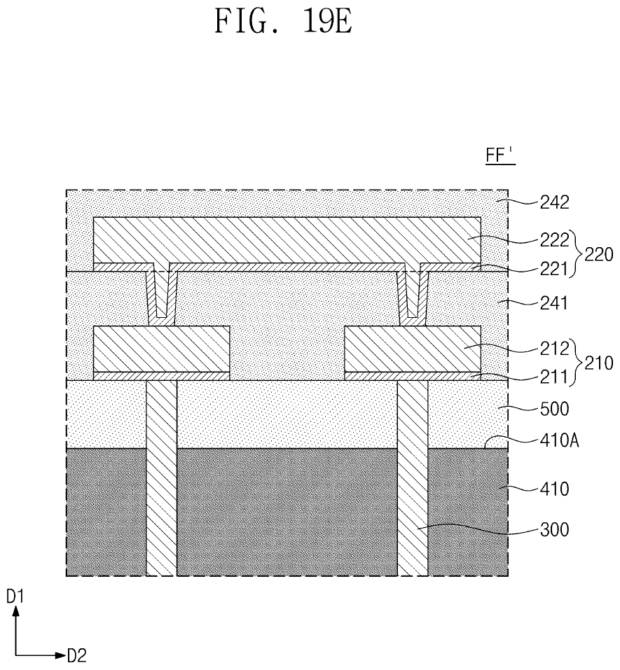

FIGS. 8, 9, 10, 11, 12, 13, 15, 18, and 20 illustrate a manufacturing process of a semiconductor package according to some example embodiments of inventive concepts. FIG. 14 is an enlarged view of CC′ of FIG. 13 and illustrates the manufacturing process of a semiconductor package. FIGS. 16A, 16B, 16C, and 16D are enlarged views of DD′ in FIG. 15 and illustrate the manufacturing process of a semiconductor package. FIGS. 17A, 17B, and 17C are enlarged views of EE′ of FIG. 15 and illustrate the manufacturing process of a semiconductor package. FIGS. 19A, 19B, 19C, 19D, and 19E are enlarged views of FF′ of FIG. 18 and illustrate manufacturing processes of a semiconductor package.

Referring to FIG. 8, a plurality of semiconductor chip stacks CS may be formed on a support substrate 600. The semiconductor chip stacks CS may be arranged to be spaced apart in the second direction D2. Forming each of the semiconductor chip stacks CS may include stacking the semiconductor chips 100 in an offset manner. For example, forming each of the semiconductor chip stacks CS may include attaching a first adhesive layer AD1 attached to a second surface 100B of the semiconductor chip 100 to the support substrate 600, and attaching the first adhesive layer AD1 attached to the second surface 100B of another semiconductor chip 100 to the first surface 100A of the semiconductor chip 100 attached to the support substrate 600. In such case, an attachment position of the chips 100 may be adjusted such that the chip pads 110 of the first surface 100A of the semiconductor chip 100 are exposed from (for example, uncovered or at least partially uncovered by) the first adhesive layer AD1 on the second surface 100B of the adjacent semiconductor chip 100.

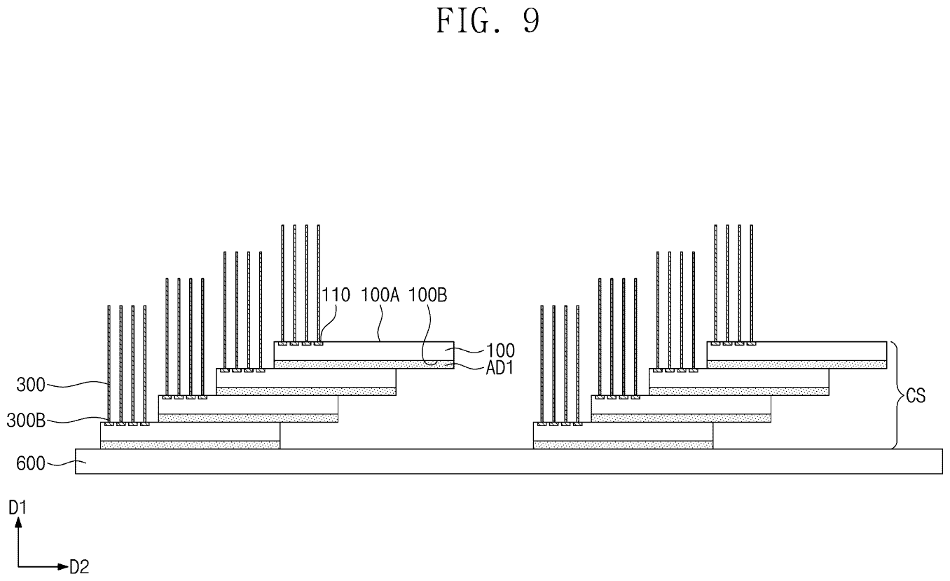

Referring to FIG. 9, vertical conductive structures 300 may be formed on the chip pads 110, respectively. The vertical conductive structures 300 may be formed through, for example, a metal wire bonding process. The metal wire bonding process may include, for example, coupling a capillary to a metal wire, placing the metal wire on the chip pads 110, lowering the capillary to attach a second end portion 300B of the metal wire to the chip pads 110, raising the capillary to tension the metal wire in a vertical direction from the second end portion 300B, and cutting the metal wire, but example embodiments are not limited thereto. A ball shape illustrated in FIG. 5 may be formed during the bonding process between the metal wire and the chip pad 110, and at least a portion of the metal wire may have a curved shape even when stretched vertically. A width or diameter of the metal wire may be, for example, about 30 μm or less, but example embodiments are not limited thereto. According to some example embodiments, forming the vertical conductive structures 300 may include forming a seed layer on the first surface 100A of the semiconductor chip 100, forming a metal pillar through an electroplating process, and forming a third seed pattern by patterning the seed layer (refer to FIG. 6). In such a case, a width diameter of the metal pillar created may be, for example, about 50 μm or less.

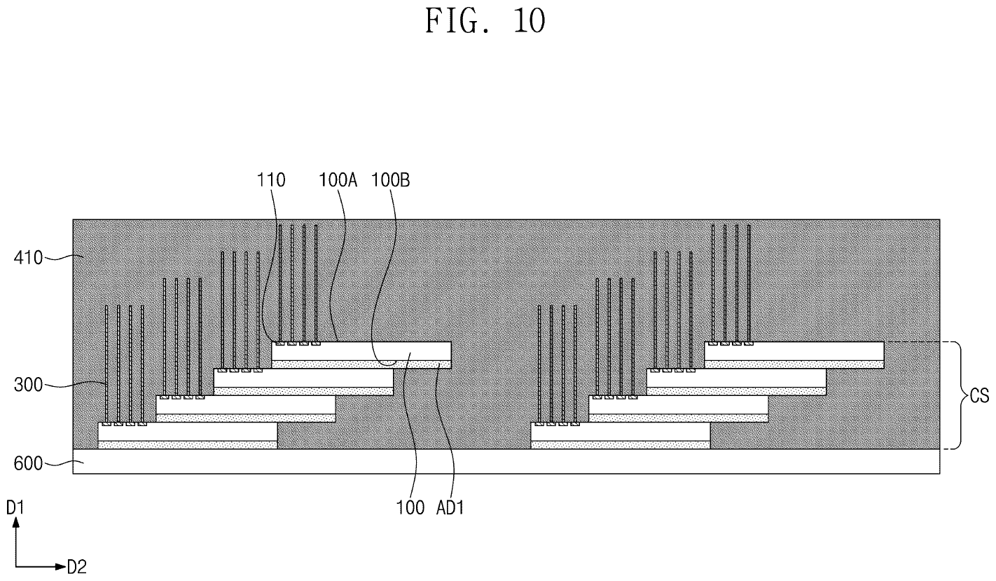

Referring to FIG. 10, a first molding 410 may be formed to cover (for example, at least partially cover) an upper surface of the support substrate 600, the exposed first surface 100A and a side surface of the semiconductor chip 100, and vertical conductive structures 300, and a space between the vertical conductive structures 300.

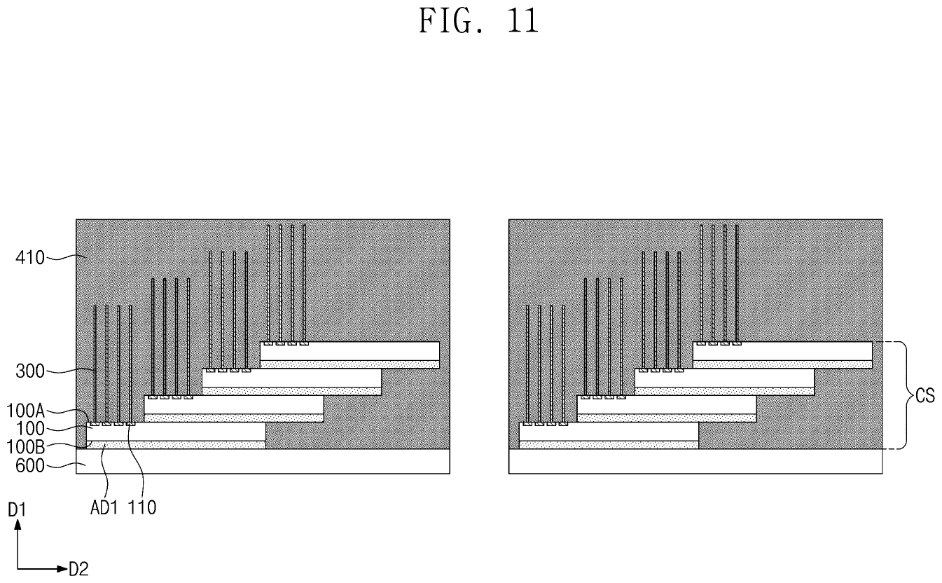

Referring to FIG. 11, a sawing process may be performed on the first molding layer 410 and the support substrate 600. Accordingly, one chip stack CS may be placed on one support substrate 600. For example, fillers near a cut surface of the first molding layer 410 may be cut by the sawing process (refer to FIG. 7), but example embodiments are not limited thereto.

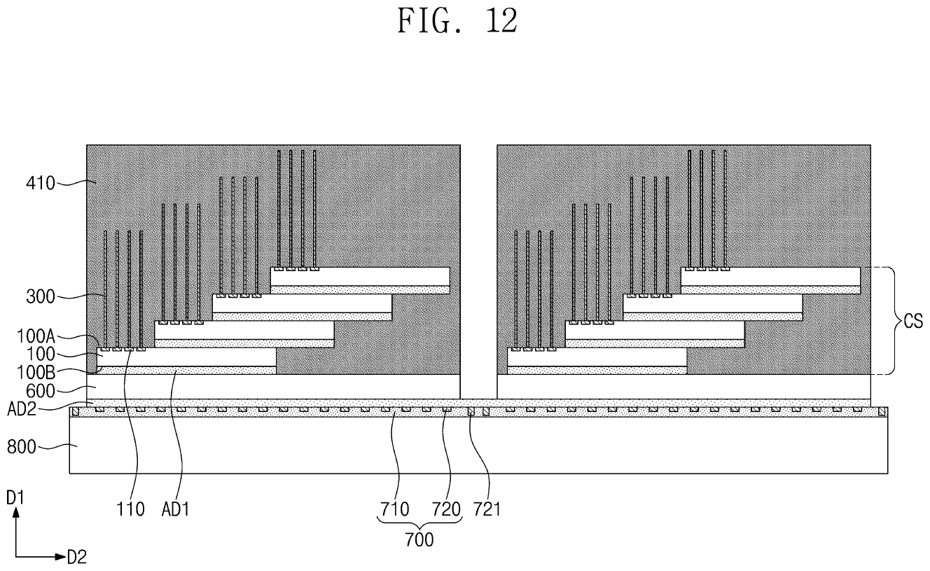

Referring to FIG. 12, a carrier substrate 800 and a dummy structure 700 on the carrier substrate 800 may be prepared. A release layer may be interposed between the carrier substrate 800 and the dummy structure 700. The carrier substrate 800 may be or include, for example, a glass substrate, but example embodiments are not limited thereto. Forming the dummy structure 700 on the carrier substrate 800 may include, for example, coating a photo-imageable dielectric on the carrier substrate 800 (or a release layer), patterning and/or curing the photo-imageable dielectric using an exposure process to form a second insulating layer 710, and forming a metal pattern 720 on the second insulating layer using, for example, an electroplating process, but example embodiments are not limited thereto. An align key 721 may be, for example, formed simultaneously with the forming of the metal pattern 720 or formed independently in another process. A second adhesive layer AD2 may be disposed on a surface of the support substrate 600 that faces the surface to which the first molding layer 410 is attached. The second adhesive layer AD2 may be attached to an upper surface of the dummy structure 700. In such a case, the align key 721 may define or easily or relatively easily confirm a position where the plurality of support substrates 600 are attached.

Referring to FIG. 13, a second molding layer 420 may be formed to cover (for example, at least partially cover) the upper surface of the dummy structure 700, the upper surface and side surface of the first molding layer 410, the side surface of the support substrate 600, and the side surface of the second adhesive layer AD2.

Referring to FIGS. 13 and 14, even when the vertical conductive structures 300 are disposed on the first surface 100A of the same semiconductor chip 100, levels of the upper surfaces of the vertical conductive structures 300 may be different or substantially different from each other. Additionally, or alternatively, the level of the upper surface of the vertical conductive structure 300 on one semiconductor chip 100 may be different from the level of the upper surface of the vertical conductive structure 300 on the other semiconductor chip 100.

Referring to FIG. 16A, the surface of the first molding layer 410 and the surface of the second molding layer 420 may be ground to expose the upper surfaces of the vertical conductive structures 300 to the outside. A level of each upper surface of the vertical conductive structures 300 may become the same or substantially the same as a result of grinding. The upper surface of the first molding layer 410, the upper surface of the second molding layer 420, and the upper surfaces of the vertical conductive structures 300 may be substantially coplanar.

Referring to FIG. 16B, portions of the first molding layer 410 and the second molding layer 420 may be selectively removed to expose the first end portion 300A of the vertical conductive structure 300. Selectively removing the first molding layer 410 and the second molding layer 420 may include, for example, at least one of a CMP process, laser drilling, and dry etching, but example embodiments are not limited thereto. The CMP process, laser drilling, =dry etching and/or the like may be performed on the entire upper surface of the first molding layer 410 and the second molding layer 420. Due to an etch rate difference between the epoxy molding compound (EMC) included in the first molding layer 410 and the second molding layer 420, and metal material(s) included in the vertical conductive structure 300, the first molding layer 410 and second molding layer 420 may be selectively removed. According to some example embodiments, even after the etching process, a portion of the first molding layer 410 may remain on the side surface 300S of the first end portion 300A of the vertical conductive structure 300, accordingly forming the first portion 411 of FIG. 3.

Referring to FIG. 16C, a passivation layer 500 may be formed to cover the exposed first end portion 300A of the vertical conductive structure 300 and the upper surface of the first molding layer 410. Forming the passivation layer 500 may include, for example, coating a photo-imageable dielectric on the first molding layer 410, but example embodiments are not limited thereto.

Referring to FIG. 16D, a portion of the passivation layer 500 may be removed to expose the upper surface of the vertical conductive structure 300. Removing a portion of the passivation layer 500 may include a process such, for example, as grinding. In the process of removing portion of the passivation layer 500, portion of the vertical conductive structure 300 may also be removed. The upper surface of the passivation layer 500 and the upper surfaces of the vertical conductive structures 300 may be coplanar or substantially coplanar.

According to some example embodiments, after the first molding layer 410 and the second molding layer 420 of FIG. 16A are ground, as illustrated in FIG. 17A, a recess 410R may be formed (for example, defined) in the first molding layer 410 around the vertical conductive structure 300. Forming the recess 410R may include laser drilling, for example, but example embodiments are not limited thereto. The laser drilling process may be performed on a portion of the upper surface of the first molding layer 410. The first molding layer 410 between the recesses 410R may form a protrusion 410P. As illustrated in FIG. 17B, the passivation layer 500 that fills (for example, at least partially fills) the recess 410R of the first molding layer 410 and covers the exposed first end portion 300A of the vertical conductive structure and the protrusion 410P of the first molding layer 410 may be formed. Referring to FIG. 17C, a portion of the passivation layer 500 may be removed to expose the upper surface of the vertical conductive structure 300. Removing a portion of the passivation layer 500 may include a process such as grinding. A portion of the passivation layer 500 may be, for example, removed to form protective patterns 500P spaced apart from each other by the protrusions 410P of the first molding layer 410 (refer to FIG. 4).

Referring to FIGS. 18 and 19A, a first seed layer 211L may be formed to cover the upper surface of the vertical conductive structure 300 and the upper surface of the passivation layer 500. The first seed layer 211L may be formed directly on the upper surface of the passivation layer 500 and the vertical conductive structure 300. Forming the first seed layer 211L on the passivation layer 500 may prevent or hinder foreign particles from being formed and/or contaminating equipment or from being redeposited on the first seed layer 211L, compared to forming the first seed layer 211L on the first molding layer 410.

The first seed layer 211L may be formed through a deposition process such as physical vapor deposition, chemical vapor deposition, sputtering, and atomic layer deposition. The first seed layer 211L may include, for example, titanium or titanium/copper. A first photo mask pattern PM1 defining an region where a pad will be formed may be formed on the first seed layer 211L. Thereafter, the first conductive pattern 212 may be formed on the first seed layer 211L exposed from (for example, uncovered or at least partially uncovered by) the first photo mask pattern PM1 using, for example, an electroplating method.

Referring to FIG. 19B, the first photo mask pattern PM1 may be removed. Subsequently, the first seed layer 211L may be patterned using the first conductive pattern 212 as an etch mask to form the first seed pattern 211. Accordingly, the first pad 210 including the first seed pattern 211 and the first conductive pattern 212 may be formed.

Referring to FIG. 19C, a first sub-insulating layer 241 may be formed on the passivation layer 500, covering or at least partially covering a surface of the passivation layer 500 and/or the upper and side surfaces of the first pad 210. For example, a photo-imageable dielectric may be coated on the passivation layer 500. A via hole VH exposing a portion of the upper surface of the first pad 210 may be formed by exposing, developing, and curing the photo-imageable dielectric.

Referring to FIG. 19D, a second seed layer 221L may be formed on the first sub-insulating layer 241. The second seed layer 221L may cover the upper surface of the first sub-insulating layer 241 and fill a portion of the via hole VH. A second photo mask pattern PM2 may be formed on the second seed layer 221L to define a region where the second conductive pattern 222 will be formed. The second photo mask pattern PM2 may be formed in the same, substantially the same, or similar manner to the method in which the first photo mask pattern PM1 is formed.

Referring to FIG. 19E, the second photo mask pattern PM2 may be removed. Using the second conductive pattern 222 as an etch mask, the second seed layer 221L may be etched to form the second seed pattern 221. Accordingly, a redistribution pattern 220 including the second seed pattern 221 and the second conductive pattern 222 may be formed. A second sub-insulating layer 242 may be formed covering the redistribution pattern 220. Additionally, as illustrated in FIG. 18, the wiring layer 200 may be formed by forming the second pads 230 and the connection terminal 250 on the redistribution pattern 220 and the first insulating layer 240.

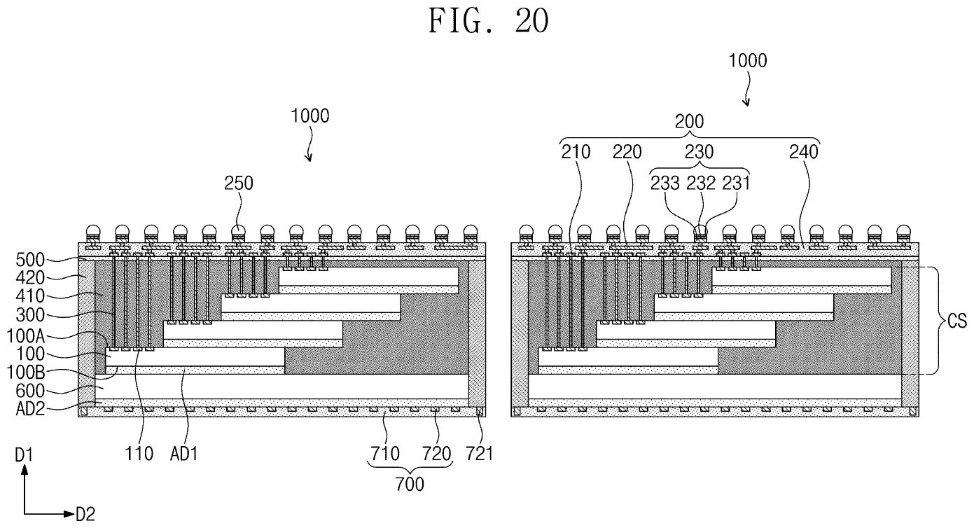

Referring to FIG. 20, the carrier substrate 800 may be removed. Before or after removing the carrier substrate 800, the wiring layer 200, the second molding layer 420, and the dummy structure 700 may be sawed to form the plurality of semiconductor packages 1000 of FIG. 1.

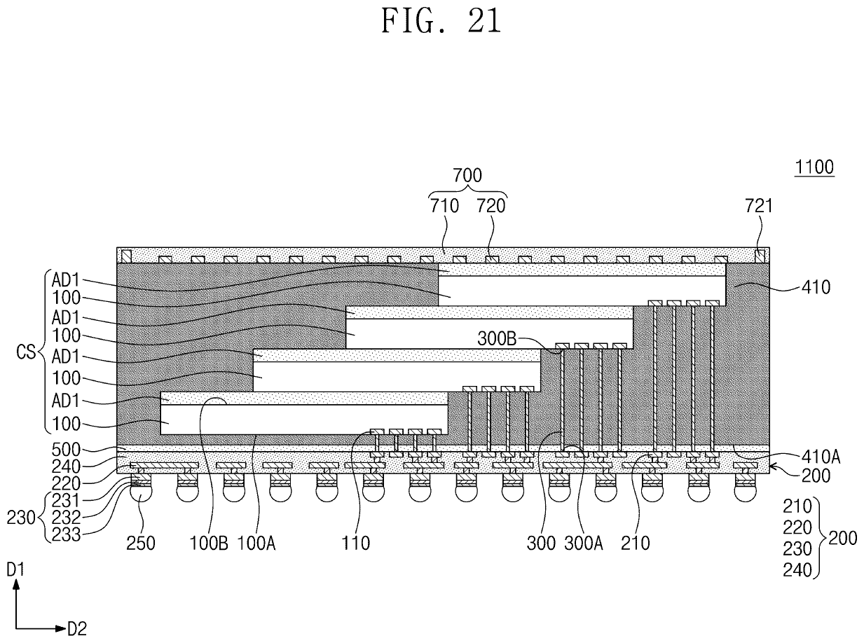

FIG. 21 is a cross-sectional view of a semiconductor package according to some example embodiments of inventive concepts. Except for those described below, descriptions that overlap the semiconductor package described in FIG. 1 will be omitted.

In the semiconductor package 1100 according to FIG. 21, the support substrate 600, the second adhesive layer AD2, and the second molding member 420 may be omitted.

Referring to FIG. 21, the first adhesive layer AD1 on the semiconductor chip 100 disposed on the uppermost chip stack CS of the semiconductor package 1100 may be in contact (for example, direct contact) with the dummy structure 700. The first molding layer 410 and the dummy structure 700 may be, for example, in contact (for example, direct contact) with each other. The dummy structure 700 may, for example, serve as a substrate on which the chip stack CS is disposed, but example embodiments are not limited thereto*.

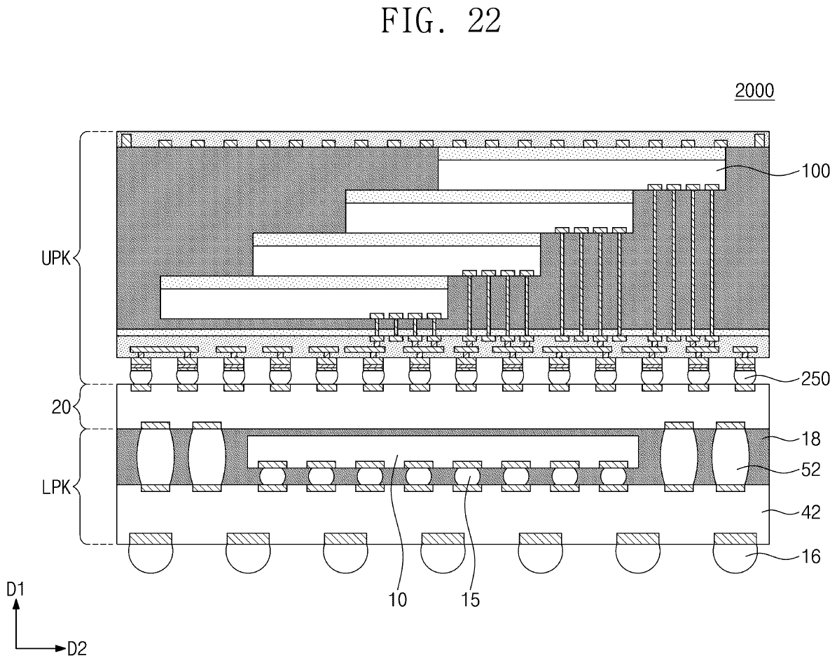

FIG. 22 is a cross-sectional view of a semiconductor package according to some example embodiments of inventive concepts.

Referring to FIG. 22, a semiconductor package 2000 according to some example embodiments may correspond to an example of a package-on-package structure. The semiconductor package 2000 may include a lower semiconductor package LPK, an upper semiconductor package UPK on the lower semiconductor package LPK, and an interposer 20 interposed therebetween. The upper semiconductor package UPK may be the same as, substantially the same as, or similar to the semiconductor package 1100 previously described with reference to FIG. 21. Alternatively, the upper package UPK may be substantially the same as the semiconductor package 1000 previously described with reference to FIG. 1.

The lower semiconductor package LPK may include a lower package substrate 42 and a lower semiconductor chip 10 mounted thereon. In, for example, a package-on-package structure, the semiconductor chip 100 of the upper semiconductor package UPK may be referred to as the upper semiconductor chip 100. For example, the lower semiconductor chip 10 may be or include a logic chip, and the upper semiconductor chip 100 may be or include, for example, a memory chip, but example embodiments are not limited thereto. The lower semiconductor chip 10 and the upper semiconductor chip 100 may include (for example, respectively include) different types of semiconductor chips.

The lower package substrate 42 may be or include a printed circuit board having or including, for example, a single-layer or multi-layer wiring structure. The lower semiconductor chip 10 may be mounted on the lower package substrate 42 using an internal connection terminal 15 using a flip chip bonding manner. An external connection terminal 16 may be attached to the lower package substrate 42. Any or all of the internal connection terminal 15 and the external connection terminal 16 may include at least one, for example, of a copper bump, a solder layer, and a solder ball. An upper surface of the lower package substrate 42 and the lower semiconductor chip 10 may be covered with a lower molding layer 18. Each of the lower molding layers 18 may contain an insulating resin such as, for example, epoxy molding compound (EMC), but example embodiments are not limited thereto.

The upper semiconductor package UPK may be connected to the interposer 20 through a connection terminal 250. The interposer IP may be electrically connected to the lower semiconductor package LPK by a package connection member 52. The package connection member 52 may include, for example, at least one of a conductive bump, a conductive pillar, a solder layer, and a solder ball. According to some example embodiments, an opening into which the package connection member 52 is inserted may be formed in the lower molding layer 18.

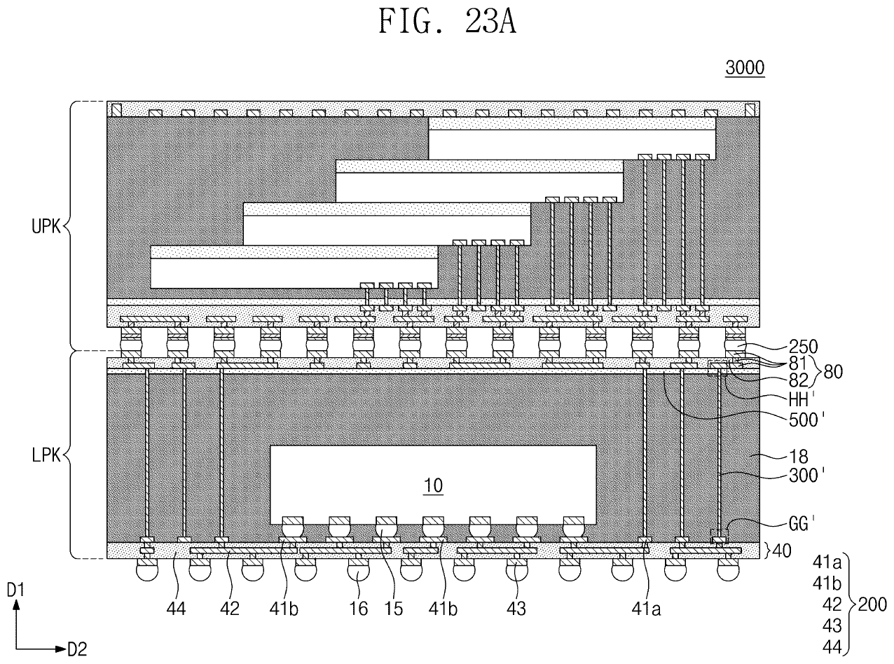

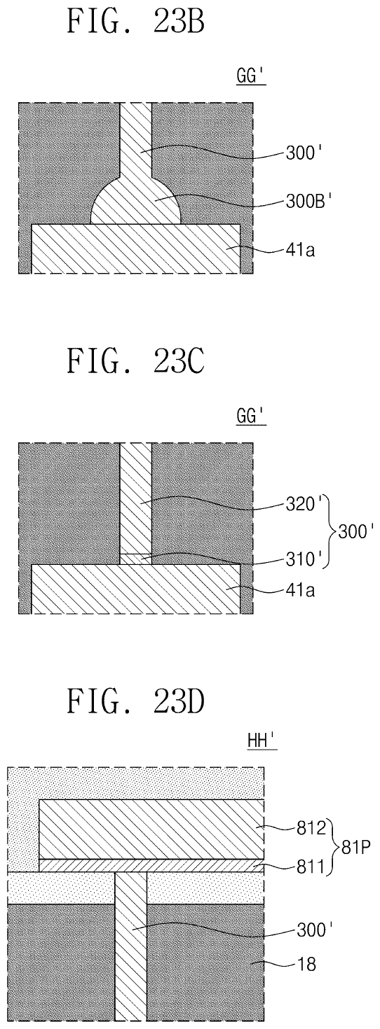

FIG. 23A is a cross-sectional view of a semiconductor package according to some example embodiments of inventive concepts. FIG. 23B is an enlarged view of GG′ in FIG. 23A. FIG. 23C is an enlarged view corresponding to GG′ in FIG. 23A. FIG. 23D is an enlarged view of HH′ in FIG. 23A.

Referring to FIG. 23A, the semiconductor package 2000 according to this example may correspond to an example of a package on package structure. This semiconductor package 2000 may include a lower semiconductor package LPK and an upper semiconductor package UPK on the lower semiconductor package LPK. The upper semiconductor package UPK may be the same as, substantially the same as, or similar to the semiconductor package 1100 previously described with reference to FIG. 21. Alternatively, the upper package UPK may be substantially the same as the semiconductor package 1000 previously described with reference to FIG. 1.

The lower semiconductor package LPK may have a chip-last or redistribution-first (RDL-first) fan-out wafer-level package structure. According to some example embodiments, unlike illustrated, the lower semiconductor package LPK may have a structure of or include, for example, a chip-first or redistribution last (RDL-last) fan-out wafer-level package.

Specifically, a lower semiconductor chip 10 may be disposed on a lower redistribution layer 40. The lower redistribution layer 40 may include a first bonding pad 41a, a second bonding pad 41b, a lower redistribution pattern 42, an external connection pad 43, and a third insulating layer 44. The first bonding pad 41a may be in contact (for example, direct contact) with a second vertical conductive structure 300′. Previously, the vertical conductive structure 300 may be referred to as the first vertical conductive structure 300. The second vertical conductive structure 300′ may include, for example, a metal wire or a metal pillar. A diameter of the second vertical conductive structure 300′ may be 50 μm or less or 30 μm or less. When the second vertical conductive structure 300′ is or includes a metal wire, the portion 300B′ of the second vertical conductive structure 300′ in contact (for example, direct contact) with the first bonding pad 41a may have, for example, a ball shape (refer to FIG. 23C). As another example, the second vertical conductive structure 300′ may include a metal pillar 320′ and a seed pattern 310′ between the metal pillar 320′ and the first bonding pad 41a (refer to FIG. 23D). The seed pattern 310′ may be in contact (for example, direct contact) with the first bonding pad 41a.

Referring again to FIG. 23A, the second bonding pad 42 may be in contact (for example, direct contact) with the internal connection terminal 15 and may be electrically connected to the lower semiconductor chip 10 through an internal connection terminal 15. An external connection terminal 16 may, for example, be disposed on the third bonding pad 43. The lower redistribution pattern 42 may connect the first bonding pad 41a, the second bonding pad 41b, and the external connection pad 43 to each other. According to some example embodiments, a space between the semiconductor chip 10 and the lower redistribution layer 40 may be filled or at least partially with, for example, an underfill layer, but example embodiments are not limited thereto. The lower redistribution layer 40 may be covered with a lower molding layer 18. An upper surface and side surfaces of the lower semiconductor chip 10 may be covered with the lower molding layer 18.

An upper redistribution layer 80 may be disposed on the lower molding layer 18. A second passivation layer 500′ may be interposed between the upper redistribution layer 80 and the lower molding layer 18. In, for example, the package-on-package structure, the passivation layer 500 of the upper package UPK may be referred to as the first passivation layer 500.

Referring to FIGS. 23A and 23D, the upper redistribution layer 80 may include upper redistribution patterns 81 and a fourth insulating layer 82. The second vertical conductive structure 300′ may penetrate the lower molding layer 18 and the second passivation layer 500′ and be connected to the upper redistribution patterns 81. The second vertical conductive structure 300′ may electrically connect the upper redistribution layer 80 and the lower redistribution layer 40. For example, the pad portion 81P of the upper redistribution pattern 81 that is in contact (for example, direct contact) with the second vertical conductive structure 300′ may be in direct contact with the second vertical conductive structure 300′. That the pad portion 81P is in direct contact with the second vertical conductive structure 300′ means that the pad portion 81P of the upper redistribution pattern 81, which has a diameter larger or substantially larger than a diameter of the second vertical conductive structure 300′, is positioned at the same level as a contact surface between the second vertical conductive structure 300′ and the upper redistribution pattern 81. The pad portion 81P may include a seed pattern 811 and a conductive pattern 812, and the seed pattern 811 may be in direct contact with the second passivation layer 500′. The second passivation layer 500′ may include same or similar insulating material(s) as the first passivation layer 500′ and/or the fourth insulating layer 82. Description of the second vertical conductive structure 300′, the pad portion 81P, and the second passivation layer 500′ may be the same, substantially the same, or similar as description of the first vertical conductive structure 300 and the first pad 210 previously described in FIGS. 2 to 4.

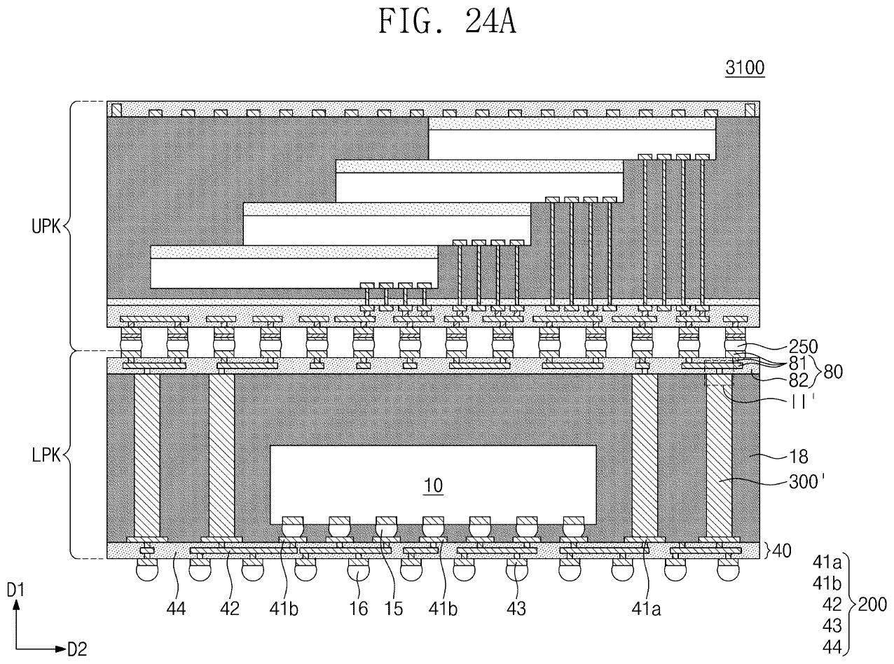

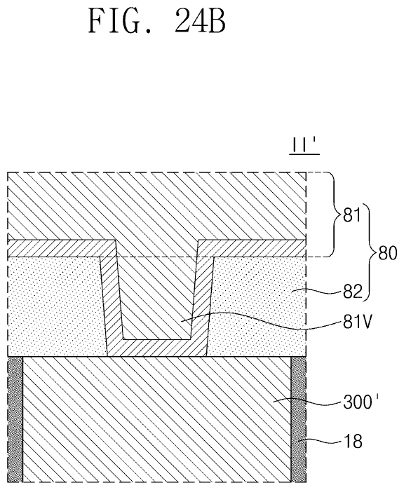

FIG. 24A is a cross-sectional view of a semiconductor package according to some example embodiments of inventive concepts. FIG. 24B is an enlarged view of II″ of FIG. 24A. Except for those described below, descriptions that overlap those described in FIG. 23A, will be omitted.

Referring to FIGS. 24A and 24B, in a semiconductor package 3100 according to this example, a diameter of the second vertical conductive structure 300′ may be larger than 50 μm. For example, the diameter of the second vertical conductive structure 300′ may be 60 μm to 200 μm. The second vertical conductive structure 300′ may include, for example, a metal pillar 320′ and a seed pattern 310′ between the metal pillar 320′ and the first bonding pad 41a, as illustrated in FIG. 23C.

The upper redistribution layer 80 may be in direct contact with the lower molding layer 18. The second vertical conductive structure 300′ may penetrate the lower molding layer 18 and electrically connect the upper redistribution layer 80 and the lower redistribution layer 40. Specifically, a via portion 81V of the upper redistribution pattern 81 in contact with the second vertical conductive structure 300′ may be in direct contact with the second vertical conductive structure 300′. That the via portion 81V is in direct contact with the second vertical conductive structure 300′ may be understood to mean that the via portion 81V of the upper redistribution pattern 81, which has a diameter larger than that of the second vertical conductive structure 300′, is positioned at the same level as the contact surface between the second vertical conductive structure 300′ and the upper redistribution pattern 81. The second vertical conductive structure 300′ may not protrude (for example, extend) beyond the lower molding layer 18 and may not extend further upward.

The semiconductor package according to inventive concepts may include the passivation layer interposed between the molding layer and the pad of the wiring layer. The vertical conductive structure directly connected to the semiconductor chip may be connected to the pad of the wiring layer across (for example, through or by) the molding layer and the passivation layer. The pad includes the seed pattern, and the seed pattern may be spaced apart from the molding layer and may be in contact (for example, direct contact) with the passivation layer. As the bonding force between the seed pattern and the passivation layer is strong, the possibility of delamination therebetween may be reduced. As a result, the reliability of the semiconductor package may be increased.

While example embodiments are described above, a person ordinarily skilled in the art may understand that many modifications and variations are made without departing from the spirit and scope of inventive concepts as in the following claims. Accordingly, the example embodiments of inventive concepts should be considered in all respects as illustrative and not restrictive, with the spirit and scope of inventive concepts being indicated by the appended claims.

Terms, such as first, second, etc. may be used herein to describe various elements, but these elements should not be limited by these terms. The above terms are used only for the purpose of distinguishing one component from another. For example, a first element may be termed a second element, and, similarly, a second element may be termed a first element, without departing from the scope of the present disclosure.

Singular expressions may include plural expressions unless the context clearly indicates otherwise. Terms, such as “include” or “has” may be interpreted as adding features, numbers, steps, operations, components, parts, or combinations thereof described in the specification.

It will be understood that when an element or layer is referred to as being “on”, “connected to”, “coupled to”, “attached to”, or “in contact with” another element or layer, it can be directly on, connected to, coupled to, attached to, or in contact with the other element or layer, or intervening elements or layers may be present. In contrast, when an element is referred to as being “directly on”, “directly connected to”, “directly coupled to”, “directly attached to”, or “in direct contact with” another element or layer, there are no intervening elements or layers present. As used herein, the term “and/or” includes any and all combinations of one or more of the associated listed items.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same.

Spatially relative terms (e.g., “beneath,” “below,” “lower,” “above,” “upper,” and the like) may be used herein for ease of description to describe one element or feature's relationship to another element(s) or feature(s) as illustrated in the figures. It should be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” may encompass both an orientation of above and below. The device may be otherwise oriented (rotated 90 degrees or at other at other orientations) and the spatially relative descriptors used herein interpreted accordingly.

What is claimed is:

1. A semiconductor package comprising:
a semiconductor chip stack including offset-stacked semiconductor chips;
a wiring layer on the semiconductor chip stack;
a vertical conductive structure connecting one of the semiconductor chips to the wiring layer;
a molding layer at least partially covering
the semiconductor chip stack, and
each side surface of the vertical conductive structures; and
a passivation layer between the wiring layer and the molding layer,
wherein the wiring layer includes a pad in direct contact with the vertical conductive structure, and
wherein the pad is spaced apart from the molding layer with the passivation layer therebetween.

2. The semiconductor package of claim 1, wherein a width of the pad is greater than a width of the vertical conductive structure.

3. The semiconductor package of claim 1, wherein the pad includes a seed pattern, and
wherein the seed pattern is in contact with the passivation layer.

4. The semiconductor package of claim 3, wherein the seed pattern includes titanium.

5. The semiconductor package of claim 1, wherein the vertical conductive structure extend through the molding layer and the passivation layer to the pad.

6. The semiconductor package of claim 1, wherein the passivation layer includes an insulating material different from a material of the molding layer.

7. The semiconductor package of claim 1, wherein a thickness of the passivation layer is 0.1 μm to 2 μm.

8. The semiconductor package of claim 1, wherein the vertical conductive structure includes a vertical metal wire, or copper pillar, or both the metal wire and the metal pillar.

9. The semiconductor package of claim 1, wherein the passivation layer includes a plurality of passivation layers,
wherein the molding layer defines a recess, and
wherein the plurality of passivation layers are in the recess.

10. The semiconductor package of claim 1, wherein the vertical conductive structure includes a plurality of vertical conductive structures, each connecting one of the semiconductor chips to the wiring layer,
wherein the molding layer includes a first portion in contact with side surfaces of the plurality of vertical conductive structures and a second portion between ones of the plurality of vertical conductive structures, and
wherein a level of a lower surface of the first portion is lower than a level of a lower surface of the second portion.

11. The semiconductor package of claim 1, wherein a contact area between the vertical conductive structure and the pad is equal to the cross-sectional area of the vertical conductive structure.

12. A semiconductor package comprising:
a semiconductor chip stack including offset-stacked semiconductor chips;
a wiring layer spaced apart from the semiconductor chip stack;
a vertical conductive structure connecting one of the semiconductor chips to the wiring layer; and
a molding layer at least partially covering
the semiconductor chip stack, and
each side surface of the vertical conductive structure,
wherein the vertical conductive structure includes a protruding portion that extends from the molding layer toward the wiring layer.

13. The semiconductor package of claim 12, wherein the protruding portion extends 0.1 μm to 2 μm beyond the molding layer.

14. The semiconductor package of claim 12, wherein a side surface of the protruding portion is exposed from the molding layer.

15. The semiconductor package of claim 14, further comprising a passivation layer at least partially covering the side surface of protruding portion,
wherein the passivation layer includes an insulating material different from a material of the molding layer.

16. The semiconductor package of claim 15, wherein the molding layer includes an epoxy molding compound, and
wherein the passivation layer includes a photo-imageable dielectric.

17. The semiconductor package of claim 12, wherein the vertical conductive structure includes a plurality of vertical conductive structures, each connecting one of the semiconductor chips to the wiring layer, and
wherein each of the plurality of vertical conductive structures includes a metal wire. a metal pillar, or both the metal wire and the metal pillar.

18. The semiconductor package of claim 17, wherein a width of the metal wire is 30 μm or less, and
wherein a width the metal pillar is a width of 50 μm or less.

19. A semiconductor package comprising:
a support substrate;
a semiconductor chip stack including offset-stacked semiconductor chips on the support substrate;
a wiring layer on the semiconductor chip stack;
vertical conductive structures connecting the semiconductor chips to the wiring layer;
a first molding layer at least partially covering
the semiconductor chip stack, and
each side surface of the vertical conductive structures;
a passivation layer between the wiring layer and the first molding layer;
a dummy structure on the support substrate; and
a second molding layer at least partially covering a side surface of the first molding layer and between the dummy structure and the passivation layer,
wherein the wiring layer includes a pad in contact with one of the vertical conductive structures and with the passivation layer, and
wherein the first molding layer includes an insulating material different from a material in the passivation layer, or the passivation layer includes an insulating material different from a material in the first molding layer.

20. The semiconductor package of claim 19, wherein the passivation layer includes at least one of polyimide and benzocyclobutene (BCB).
